(19) United States
(12) Patent Application Publication
(10) Pub. No.: US 2025/0248109 A1
(43) Pub. Date: Jul. 31, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke ASABA, Himeji Hyogo (JP); Hiroshi KONO, Himeji Hyogo (JP)

(21) Appl. No.: 19/076,962

(22) Filed: Mar. 11, 2025

Related U.S. Application Data
(63) Continuation of application No. PCT/JP2024/005965, filed on Feb. 20, 2024.

(30) Foreign Application Priority Data
Jul. 18, 2023 (JP) 2023-116912

(51) Int. Cl. H10D 84/00; H10D 8/00; H10D 8/60; H10D 30/63; H10D 62/10; H10D 62/60; H10D 62/832; H10D 64/64

(52) U.S. Cl. CPC H10D 84/101; H10D 8/411; H10D 8/60; H10D 30/63; H10D 62/124; H10D 62/60; H10D 62/8325; H10D 64/64

(57) ABSTRACT

According to one embodiment, a semiconductor device includes a first electrode, a second electrode, a third electrode, a first semiconductor member, a second semiconductor member, a third semiconductor member, and a fourth semiconductor member. The first semiconductor member is of a first conductivity type, and includes a first partial region, a second partial region, a third partial region, a fourth partial region, and a fifth partial region. The fifth partial region is in Schottky contact with the second electrode. The second semiconductor member is of a second conductivity type, and includes a first portion and a second portion. The third semiconductor member is of the second conductivity type, and includes a first semiconductor portion, a second semiconductor portion, and a third semiconductor portion. The fourth semiconductor member is of the first conductivity type, and includes a first semiconductor region and a second semiconductor region.

### CROSS-REFERENCE TO RELATED APPLICATIONS

This is a continuation application of International Application PCT/JP2024/005965, filed on Feb. 20, 2024. This application also claims priority to Japanese Patent Application No. 2023-116912, filed on Jul. 18, 2023. The entire contents of which are incorporated herein by reference.

### FIELD

Embodiments described herein generally relate to a semiconductor device.

### BACKGROUND

For example, it is desired to improve the characteristics of semiconductor devices including Schottky barrier diodes and the like.

### BRIEF DESCRIPTION OF THE DRAWINGS

FIG. 1 is a schematic perspective view illustrating a semiconductor device according to a first embodiment;

FIG. 2 is a schematic cross-sectional view illustrating the semiconductor device according to the first embodiment;

FIG. 3 is a schematic cross-sectional view illustrating the semiconductor device according to the first embodiment;

FIG. 4 is a schematic cross-sectional view illustrating the semiconductor device according to the first embodiment;

FIG. 5 is a schematic plan view illustrating the semiconductor device according to the first embodiment;

FIG. 6 is a schematic plan view illustrating semiconductor device according to a second embodiment; and

FIG. 7 is a schematic plan view illustrating semiconductor device according to the second embodiment.

### DETAILED DESCRIPTION

According to one embodiment, a semiconductor device includes a first electrode, a second electrode, a third electrode, a first semiconductor member, a second semiconductor member, a third semiconductor member, and a fourth semiconductor member. The third electrode extends along a second direction crossing a first direction from the first electrode to the second electrode. The first semiconductor member is of a first conductivity type. The first semiconductor member includes a first partial region, a second partial region, a third partial region, a fourth partial region, and a fifth partial region. The first partial region is provided between the first electrode and the third electrode in the first direction. A third direction from the first partial region to the second partial region crosses a plane including the first direction and the second direction. The third partial region is provided between the first partial region and the third electrode in the first direction. A direction from the second partial region to the fourth partial region is along the second direction. A direction from the fourth partial region to the fifth partial region is along the first direction. The fifth partial region is in Schottky contact with the second electrode. The second semiconductor member is of a second conductivity type. The second semiconductor member includes a first portion and a second portion. The third semiconductor member is of the second conductivity type. The first portion is provided between the second partial region and the third semiconductor member in the first direction. A direction from at least a portion of the third semiconductor member to the fifth partial region is along the second direction. The third semiconductor member includes a first semiconductor portion, a second semiconductor portion, and a third semiconductor portion. A direction from the first semiconductor portion to the third semiconductor portion is along the third direction. A direction from the third semiconductor portion to the second semiconductor portion is along the second direction. The third semiconductor portion is electrically connected to the second electrode. A third impurity concentration of the second conductivity type of the third semiconductor member is higher than a second impurity concentration of the second conductivity type of the second semiconductor member. The fourth semiconductor member is of the first conductivity type. The fourth semiconductor member includes a first semiconductor region and a second semiconductor region. The first semiconductor portion is provided between the first portion and the first semiconductor region in the first direction. The second semiconductor portion is provided between the first portion and the second semiconductor region in the first direction. The second semiconductor region is electrically connected to the second electrode. The second portion is provided between the third partial region and the first semiconductor portion, between the third partial region and the first semiconductor region, between the third partial region and the second semiconductor portion, and between the third partial region and the second semiconductor region in the third direction. A second semiconductor region length of the second semiconductor region in the third direction is longer than a first semiconductor region length of the first semiconductor region in the third direction. A fourth impurity concentration of the first conductivity type in the fourth semiconductor member is higher than a first impurity concentration of the first conductivity type in the first semiconductor member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

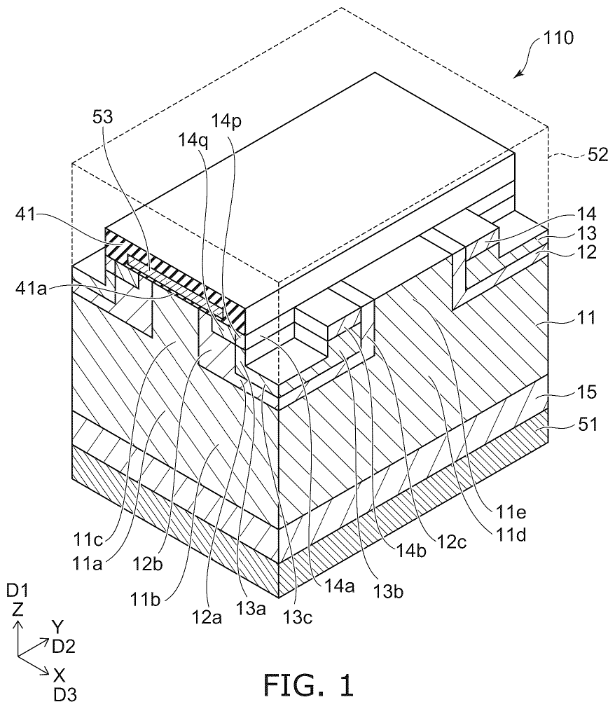

FIG. 1 is a schematic perspective view illustrating a semiconductor device according to a first embodiment.

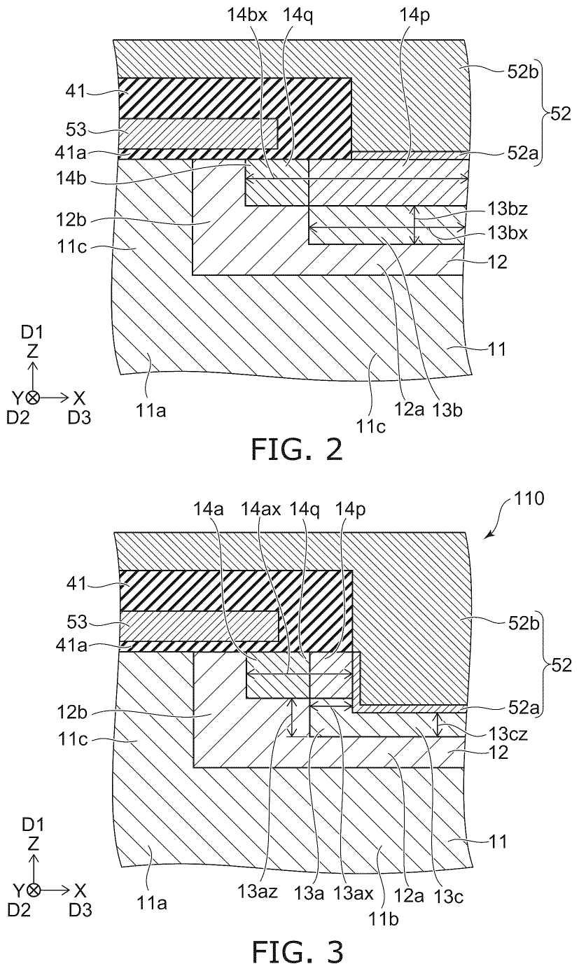

FIGS. 2 to 4 are schematic cross-sectional views illustrating the semiconductor device according to the first embodiment.

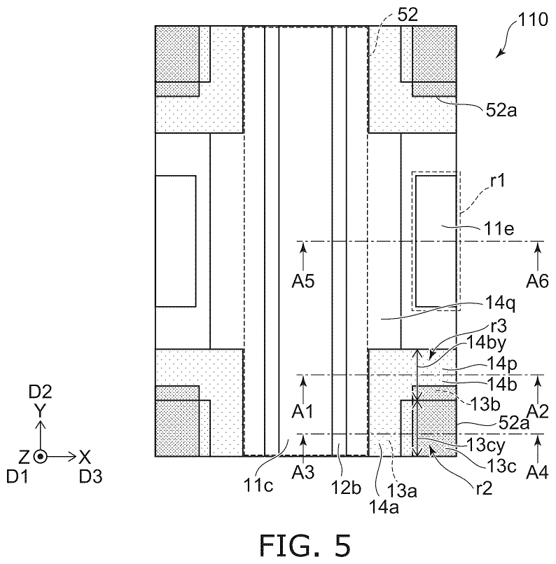

FIG. 5 is a schematic plan view illustrating the semiconductor device according to the first embodiment.

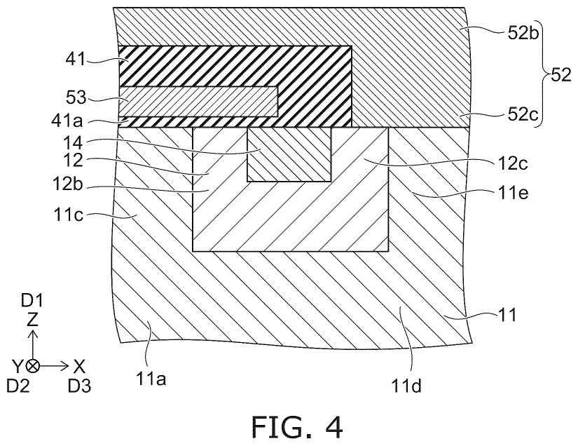

FIG. 2 is a sectional view taken along line A1-A2 in FIG. 5. FIG. 3 is a sectional view taken along the line A3-A4 in FIG. 5. FIG. 4 is a sectional view taken along the line A5-A6 in FIG. 5.

As shown in FIG. 1, a semiconductor device 110 according to the embodiment includes a first electrode 51, a second electrode 52, a third electrode 53, a first semiconductor member 11, a second semiconductor member 12, a third semiconductor member 13, and a fourth semiconductor member 14.

A first direction D1 from the first electrode 51 to the second electrode 52 is defined as a Z-axis direction. A direction perpendicular to the Z-axis direction is defined as an X-axis direction. A direction perpendicular to the Z-axis direction and the X-axis direction is defined as a Y-axis direction.

The third electrode 53 extends along a second direction D2. The second direction D2 crosses the first direction D1 from the first electrode 51 to the second electrode 52. The second direction D2 may be, for example, the Y-axis direction.

The first semiconductor member 11 is of a first conductivity type. The first semiconductor member 11 includes a first partial region 11a, a second partial region 11b, a third partial region 11c, a fourth partial region 11d, and a fifth partial region 11e. The first partial region 11a is provided between the first electrode 51 and the third electrode 53 in the first direction D1. A third direction D3 from the first partial region 11a to the second partial region 11b crosses a plane including the first direction D1 and the second direction D2. The third direction D3 is, for example, the X-axis direction.

The third partial region 11c is provided between the first partial region 11a and the third electrode 53 in the first direction D1. A direction from the second partial region 11b to the fourth partial region 11d is along the second direction D2. A direction from the fourth partial region 11d to the fifth partial region 11e is along the first direction D1. The fifth partial region 11e makes Schottky contact with the second electrode 52. In first partial region 11a, the second partial region 11b, the third partial region 11c, the fourth partial region 11d, and the fifth partial region 11e, the mutual boundaries may be clear or unclear.

The second semiconductor member 12 is of a second conductivity type. The first conductivity type is one of n-type and p-type. The second conductivity type is the other of n-type and p-type. In the following, it is assumed that the first conductivity type is n-type and the second conductivity type is p-type.

The second semiconductor member 12 includes a first portion 12a and a second portion 12b. As described later, the second semiconductor member 12 may include a third portion 12c. In the first portion 12a, the second portion 12b, and the third portion 12c, the mutual boundaries may be clear or unclear.

The third semiconductor member 13 is of the second conductivity type. The first portion 12a is provided between the second partial region 11b and the third semiconductor member 13 in the first direction D1. A direction from at least a portion 25 of the third semiconductor member 13 to the fifth partial region 11e is along the second direction D2.

The third semiconductor member 13 includes a first semiconductor portion 13a, a second semiconductor portion 13b, and a third semiconductor portion 13c. A direction from the first semiconductor portion 13a to the third semiconductor portion 13c is along the third direction D3. A direction from the third semiconductor portion 13c to the second semiconductor portion 13b is along the second direction D2. The third semiconductor portion 13c is electrically connected to the second electrode 52. For example, the third semiconductor portion 13c makes ohmic contact with the second electrode 52. In the first semiconductor portion 13a, the second semiconductor portion 13b, and the third semiconductor portion 13c, mutual boundaries may be clear or unclear.

A third impurity concentration of the second conductivity type of the third semiconductor member 13 is higher than a second impurity concentration of the second conductivity type of the second semiconductor member 12. The second semiconductor member 12 is, for example, a p-type region. The third semiconductor member 13 is, for example, a p⁺ region.

The fourth semiconductor member 14 is of the first conductivity type. The fourth semiconductor member 14 includes a first semiconductor region 14a and a second semiconductor region 14b. The first semiconductor portion 13a is provided between the first portion 12a and the first semiconductor region 14a in the first direction D1. The second semiconductor portion 13b is provided between the first portion 12a and the second semiconductor region 14b in the first direction D1. The second semiconductor region 14b is electrically connected to the second electrode 52. For example, the second semiconductor region 14b makes ohmic contact with the second electrode 52. The boundary between the first semiconductor region 14a and the second semiconductor region 14b may be clear or unclear.

The second portion 12b is provided between the third partial region 11c and the first semiconductor portion 13a, between the third partial region 11c and the first semiconductor region 14a, between the third partial region 11c and the second semiconductor portion 13b, and between the third partial region 11c and the second semiconductor region 14b, in the third direction D3 (see FIGS. 2 and 3).

A fourth impurity concentration of the first conductivity type in the fourth semiconductor member 14 is higher than a first impurity concentration of the first conductivity type in the first semiconductor member 11. The first semiconductor member 11 includes, for example, an n-type region. The first semiconductor member 11 may further include, for example, an n⁻ region. The fourth semiconductor member 14 includes an n⁺ region. The fourth semiconductor member 14 may further include an n⁺⁺ region.

As shown in FIG. 2, a length of the second semiconductor region 14b in the third direction D3 is defined as a second semiconductor region length 14bx. As shown in FIG. 3, a length of the first semiconductor region 14a in the third direction D3 is defined as a first semiconductor region length 14ax. The second semiconductor region length 14bx is longer than the first semiconductor region length 14ax.

As shown in FIG. 1, in this example, at least a portion of the second semiconductor portion 13b is provided between the third semiconductor portion 13c and the fifth partial region 11e in the third direction D3. For example, a position of the second semiconductor region 14b in the second direction D2 is between a position of the third semiconductor portion 13c in the second direction D2 and a position of the fifth partial region 11e in the second direction D2.

In the semiconductor device 110, a current flowing between the first electrode 51 and the second electrode 52 can be controlled by a potential of the third electrode 53. The potential of the third electrode 53 may be, for example, a potential based on the potential of the second electrode 52. The first electrode 51 functions, for example, as a drain electrode. The second electrode 52 functions, for example, as a source electrode. The third electrode 53 functions as, for example, a gate electrode. The semiconductor device 110 is, for example, a transistor.

As shown in FIG. 1, the semiconductor device 110 may further include a first insulating member 41. The first insulating member 41 includes a first insulating region 41a. At least a portion of the first insulating region 41a is provided between the third partial region 11c and the third electrode 53. A portion of the first insulating member 41 may be provided between the fourth semiconductor member 14 and the third electrode 53. The semiconductor device 110 is a MOSFET (Metal-Oxide-Semiconductor Field Effect Transistor).

As already explained, in the semiconductor device 110, the fifth partial region 11e that makes a Schottky junction with the second electrode 52 is provided. The region including the fifth partial region 11e functions as, for example, an SBD (Schottky Barrier Diode). The third partial region 11c corresponds to, for example, a JFET (Junction Field Effect Transistor) region. The region including the fourth semiconductor member 14 functions as a p-n body diode. In the semiconductor device 110, by providing the SBD, a current flows through the SBD, for example, when a reverse voltage is applied. Thereby, it becomes difficult for the p-n body diode to turn on.

In the cross section (cross section including the second semiconductor region 14b) shown in FIG. 2, a length of the boundary of the second semiconductor region 14b in contact with the second electrode 52 is longer than a length of the boundary of the second semiconductor portion 13b in contact with the second electrode 52. In the region shown in FIG. 2, the area of the n-type contact region is larger than the area of the p-type contact region.

In the cross section shown in FIG. 3 (the cross section including the third semiconductor portion 13c), a length of the boundary of the third semiconductor portion 13c in contact with the second electrode 52 is longer than a length of the boundary of the first semiconductor region 14a in contact with the second electrode 52. In the region shown in FIG. 3, the area of the p-type contact region is larger than the area of the n-type contact region.

In the semiconductor device 110, two types of regions are provided with different relative relationships between the area of the n-type contact region and the area of the p-type contact region. Thereby, it becomes easy to cause the characteristics of the semiconductor device 110 to the desired state. When the area of the n-type contact region is large, for example, contact resistance can be reduced, and, for example, low on-resistance can be obtained. When the area of the p-type contact region is large, for example, high-speed switching can be obtained. According to the embodiment, a semiconductor device with improved characteristics can be provided.

As shown in FIG. 5, the semiconductor device 110 includes a first region r1, a second region r2, and a third region r3. The first region r1 corresponds to the region where the fifth partial region 11e is provided. The second region r2 corresponds to a region where the third semiconductor portion 13c is provided. The third region r3 corresponds to a region where the second semiconductor region 14b is provided. The first region r1 corresponds to the SBD region. The second region r2 corresponds to a region where the area of the p-type contact region is large (p-contact region). The third region r3 corresponds to a region where the area of the n-type contact region is large (n-contact region).

In the semiconductor device 110, the SBD region, the p-contact region, and the n-contact region are arranged compactly along the second direction D2. A compact semiconductor device with good characteristics can be provided. According to the embodiment, a semiconductor device with improved characteristics can be provided.

As shown in FIG. 5, a length of the third semiconductor portion 13c along the second direction D2 is defined as a third width 13cy. A length of the second semiconductor region 14b along the second direction D2 is defined as a second width 14by. In one example, a ratio of the third width 13cy to the second width 14by is, for example, not less than 0.1 and not more than 10. For example, it is easy to obtain well-balanced characteristics.

In the embodiment, the second semiconductor region length 14bx may be, for example, 1.1 times or more the first semiconductor region length 14ax. The second semiconductor region length 14bx may be, for example, 1.3 times or more the first semiconductor region length 14ax. The second semiconductor region length 14bx may be, for example, 10 times or less the first semiconductor region length 14ax. The second semiconductor region length 14bx may be, for example, five times or less the first semiconductor region length 14ax. In the semiconductor device 110, for example, the second semiconductor region length 14bx (see FIG. 2) may be not less than 0.1 μm and not more than 3 μm. The first semiconductor region length 14ax (see FIG. 3) may be, for example, not less than 0.2 μm and not more than 5 μm.

As shown in FIG. 2, a length of the second semiconductor portion 13b in the third direction D3 is defined as a second semiconductor portion length 13bx. As shown in FIG. 3, a length of the first semiconductor portion 13a in the third direction D3 is defined as a first semiconductor portion length 13ax. The second semiconductor portion length 13bx is longer than the first semiconductor portion length 13ax.

As shown in FIG. 3, in the third semiconductor member 13, the thick region corresponds to the first semiconductor portion 13a. The thin portion corresponds to the third semiconductor portion 13c. A length of the first semiconductor portion 13a in the first direction D1 is defined as a first thickness 13az. A length of the third semiconductor portion 13c in the first direction D1 is defined as a third thickness of 13cz. The third thickness 13cz is thinner than the first thickness 13az. For example, the first thickness 13az may be not less than 1.1 times and not more than 5 times the third thickness 13cz. For example, the first thickness 13az may be, for example, not less than 0.1 μm and not more than 0.5 μm. The third thickness 13cz may be not less than 20 nm and not more than 300 nm.

As shown in FIG. 2, a length of the second semiconductor portion 13b in the first direction D1 is defined as a second thickness 13bz. The third thickness 13cz is thinner than the second thickness 13bz. For example, the second thickness 13bz may be not less than 1.1 times and not more than 5 times the third thickness 13cz. For example, the second thickness 13bz may be, for example, not less than 0.1 μm and not more than and 0.5 μm.

In one example, the thickness (length in the Z-axis direction) of the first semiconductor region 14a is, for example, not less than 20 nm and not more than 300 nm. The thickness (length in the Z-axis direction) of the first portion 12a may be, for example, not less than 50 nm and not more than 500 nm. The thickness (length in the Z-axis direction) of the second portion 12b may be, for example, not less than 200 nm and not more than 800 nm.

As shown in FIGS. 2, 3, and 5, the fourth semiconductor member 14 may include a high concentration region 14p and a low concentration region 14q. The high concentration region 14p is provided between the low concentration region 14q and second electrode 52. The impurity concentration of the first conductivity type in the high concentration region 14p is higher than the impurity concentration of the first conductivity type in the low concentration region 14q. The high concentration region 14p is, for example, an n⁺⁺ region. The low concentration region 14q is, for example, an n⁺ region.

When the fourth semiconductor member 14 includes the high concentration region 14p and the low concentration region 14q, the impurity concentration of the second conductivity type (fourth impurity concentration) in the fourth semiconductor member 14 may be the average of the impurity concentrations of the second conductivity type in the high concentration region 14p and the low concentration region 14q.

As shown in FIGS. 2 and 3, the second electrode 52 may include a first electrode portion 52a and a second electrode portion 52b. The first electrode portion 52a is provided between the third semiconductor member 13 and the second electrode portion 52b and between the fourth semiconductor member 14 and the second electrode portion 52b. For example, at least a portion of the first electrode portion 52a is provided between the third semiconductor portion 13c and the second electrode portion 52b and between the second semiconductor region 14b and the second electrode portion 52b in the first direction D1. The first electrode portion 52a includes, for example, silicide. For example, the first electrode portion 52a may include, for example, NiSi. The second electrode portion 52b may include, for example, a metal such as aluminum.

As shown in FIG. 4, the second electrode 52 may include a third electrode portion 52c. The third electrode portion 52c faces the fifth partial region 11e. For example, the third electrode portion 52c may be provided between the fifth partial region 11e and the second electrode portion 52b. The third electrode portion 52c includes, for example, at least one selected from the group consisting of Ni, Ti, V, and Mo. A Schottky junction is obtained in the region including the third electrode portion 52c.

As shown in FIGS. 1 and 4, the second semiconductor member 12 may include a third portion 12c. At least a portion of the third portion 12c is provided between the third semiconductor member 13 and the fifth partial region 11e and between the fourth semiconductor member 14 and the fifth partial region 11e in the second direction D2. As shown in FIG. 4, a portion of the third portion 12c is provided between the second portion 12b and the fifth partial region 11e in the third direction D3. A portion of the third portion 12c is provided between the fourth semiconductor member 14 and the fifth partial region 11e in the third direction D3.

As shown in FIG. 1, the semiconductor device 110 may further include a fifth semiconductor member 15 of the first conductivity type. The fifth semiconductor member 15 is provided between the first electrode 51 and the first semiconductor member 11 in the first direction D1. A fifth impurity concentration of the first conductivity type in the fifth semiconductor member 15 is higher than the first impurity concentration in the first semiconductor member 11. The fifth semiconductor member 15 may correspond to, for example, at least one of a buffer layer and a substrate. A low resistance electrical connection is obtained.

### Second Embodiment

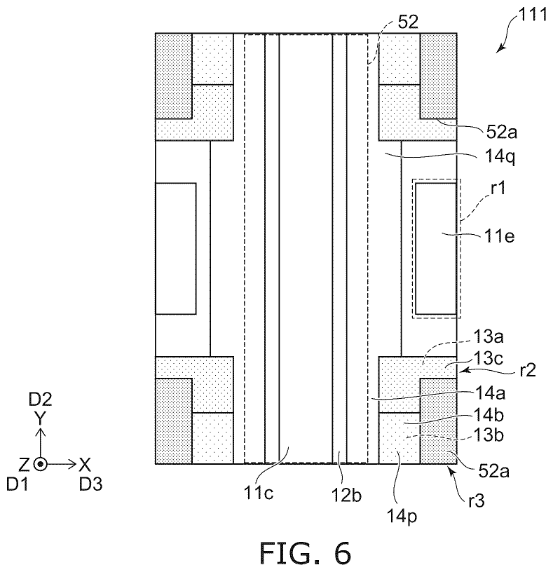

FIG. 6 is a schematic plan view illustrating a semiconductor device according to the second embodiment.

As shown in FIG. 6, in a semiconductor device 111 according to the embodiment, the positional relationship between the third semiconductor portion 13c of the third semiconductor member 13 and the second semiconductor region 14b of the fourth semiconductor member 14 is different from the positional relationship in the semiconductor device 110. The configuration of the semiconductor device 111 except for this may be similar to the configuration of the semiconductor device 110.

As shown in FIG. 6, in the semiconductor device 111, at least a portion of the third semiconductor portion 13c is provided between the second semiconductor portion 13b and the fifth partial region 11e in the second direction D2. For example, the position of the third semiconductor portion 13c in the second direction D2 is between the position of the second semiconductor region 14b in the second direction D2 and the position of the fifth partial region 11e in the second direction D2.

In the semiconductor device 111, the second region r2 (p-contact region) is provided near the first region r1 (SBD). Since the current flows through the SBD when the reverse voltage is applied, the p-n body diode corresponding to the second region r2 can be more effectively prevented from being turned on. Also in the second embodiment, a semiconductor device capable of improving characteristics can be provided.

For example, since a current is injected from the second electrode 52 to the p-n diode via the silicide of the p-type contact, the body diode in the vicinity of the p-type contact is likely to be turned on. In the semiconductor device 111, the body diode operation is effectively suppressed by providing the p-type contact in the portion where the SBD dominates strongly.

As shown in FIG. 6, in the semiconductor device 111 as well, the fourth semiconductor member 14 may include the high concentration region 14p and the low concentration region 14q. As explained with reference to FIGS. 2 and 3, the high concentration region 14p is provided between the low concentration region 14q and the second electrode 52. The impurity concentration of the first conductivity type in the high concentration region 14p is higher than the impurity concentration of the first conductivity type in the low concentration region 14q.

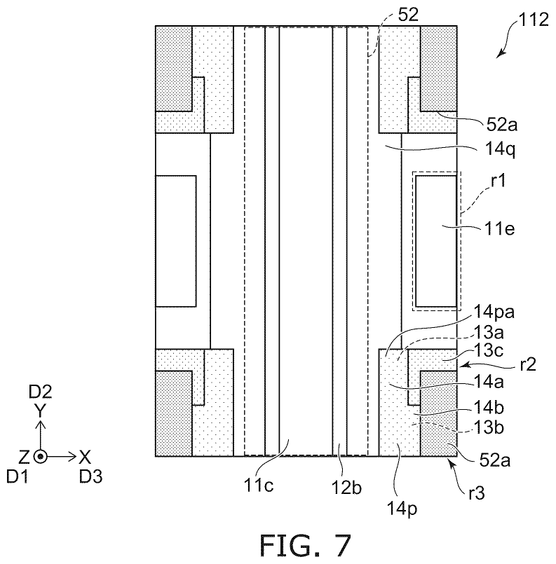

FIG. 7 is a schematic plan view illustrating a semiconductor device according to the second embodiment.

As shown in FIG. 7, in a semiconductor device 112 according to the embodiment, the shape of the high concentration region 14p is different from the shape in the semiconductor device 111. The configuration of the semiconductor device 112 except for this may be the same as the configuration of the semiconductor device 111.

In the semiconductor device 112, the position in the third direction D3 of at least a portion (for example, the portion 14pa) of the high concentration region 14p is between the position in the third direction D3 of the second portion 12b and the position in the third direction D3 of the third semiconductor portion 13c.

In the semiconductor device 112, for example, a current flowing through the third region r3 flows into the channel region via the portion 14pa. For example, it becomes easier to obtain a low on-resistance RonA.

Also in the semiconductor device 112, the position in the second direction D2 of the third semiconductor portion 13c is between the position in the second direction D2 of the second semiconductor region 14b and the position in the second direction D2 of the fifth partial region 11e. Also in the semiconductor device 112, a semiconductor device capable of improving characteristics can be provided.

For example, the third semiconductor portion 13c corresponds to a p-type contact region. The second semiconductor region 14b corresponds to an n-type contact region. A structure including the third semiconductor portion 13c and the second semiconductor region 14b forms one set. A plurality of sets may be provided. The plurality of sets may be arranged along the second direction D2. A structure including a plurality of sets forms one row. A plurality of rows may be provided. The positions in the second direction D2 of the plurality of sets included in one of the plurality of rows may be different from the positions in the second direction D2 of the plurality of sets included in another one of the plurality of rows. For example, the position in the second direction D2 of one of the plurality of sets included in one of the plurality of rows may be between the position in the second direction D2 of one of the plurality of sets included in another one of the plurality of rows and the position in the second direction D2 of another one of the plurality of sets included in another one of the plurality of rows. The plurality of sets may be arranged in a staggered manner.

In the first embodiment and the second embodiment, for example, the first semiconductor member 11, the second semiconductor member 12, the third semiconductor member 13, and the fourth semiconductor member 14 contain SiC. The first semiconductor member 11, the second semiconductor member 12, the third semiconductor member 13, and the fourth semiconductor member 14 may include at least one selected from the group consisting of 4H-SiC, 6H-SiC, and 3C-SiC. These semiconductor regions contain crystals. These semiconductor members may include silicon. These semiconductor members may include a compound semiconductor containing Ga.

For example, the first conductivity type impurity includes at least one selected from the group consisting of N, P, and As. For example, the second conductivity type impurity includes at least one selected from the group consisting of B, Al, and Ga.

In one example, the concentration of the first conductivity type impurity in the first semiconductor member 11 is, for example, not less than 1×10¹⁴ cm⁻³ and not more than 1×10¹⁷ cm⁻³. In one example, the concentration of the second conductivity type impurity in the second semiconductor member 12 is, for example, not less than 1×10¹⁶ cm⁻³ and not more than 1×10²⁰ cm⁻³. In one example, the concentration of the second conductivity type impurity in the third semiconductor member 13 is, for example, not less than 1×10¹⁹ cm⁻³ and not more than 1×10²¹ cm⁻³. In one example, the concentration of the first conductivity type impurity in the fourth semiconductor member 14 is, for example, not less than 1×10¹⁹ cm⁻³ and not more than 1×10²¹ cm⁻³. In one example, the concentration of the first conductivity type impurity in the fifth semiconductor member 15 is, for example, not less than 1×10¹⁵ cm⁻³ and not more than 1×10¹⁸ cm⁻³. The above impurity concentration may be substantially a carrier concentration, for example.

In the embodiments, information regarding length and thickness is obtained by electron microscopy or the like. Information regarding the composition of the material can be obtained by SIMS (Secondary Ion Mass Spectrometry), EDX (Energy dispersive X-ray spectroscopy), or the like.

The embodiments may include the following Technical proposals:

### Technical Proposal 1

A semiconductor device, comprising
a first electrode;
a second electrode;
a third electrode extending along a second direction crossing a first direction from the first electrode to the second electrode;
a first semiconductor member of a first conductivity type, the first semiconductor member including a first partial region, a second partial region, a third partial region, a fourth partial region, and a fifth partial region, the first partial region being provided between the first electrode and the third electrode in the first direction, a third direction from the first partial region to the second partial region crossing a plane including the first direction and the second direction, the third partial region being provided between the first partial region and the third electrode in the first direction, a direction from the second partial region to the fourth partial region being along the second direction, a direction from the fourth partial region to the fifth partial region being along the first direction, the fifth partial region being in Schottky contact with the second electrode;
a second semiconductor member of a second conductivity type, the second semiconductor member including a first portion and a second portion;
a third semiconductor member of the second conductivity type, the first portion being provided between the second partial region and the third semiconductor member in the first direction, a direction from at least a portion of the third semiconductor member to the fifth partial region being along the second direction, the third semiconductor member including a first semiconductor portion, a second semiconductor portion, and a third semiconductor portion, a direction from the first semiconductor portion to the third semiconductor portion being along the third direction, a direction from the third semiconductor portion to the second semiconductor portion being along the second direction, the third semiconductor portion being electrically connected to the second electrode, a third impurity concentration of the second conductivity type of the third semiconductor member being higher than a second impurity concentration of the second conductivity type of the second semiconductor member;
a fourth semiconductor member of the first conductivity type, the fourth semiconductor member including a first semiconductor region and a second semiconductor region, the first semiconductor portion being provided between the first portion and the first semiconductor region in the first direction, the second semiconductor portion being provided between the first portion and the second semiconductor region in the first direction, the second semiconductor region being electrically connected to the second electrode, the second portion being provided between the third partial region and the first semiconductor portion, between the third partial region and the first semiconductor region, between the third partial region and the second semiconductor portion, and between the third partial region and the second semiconductor region in the third direction, a second semiconductor region length of the second semiconductor region in the third direction being longer than a first semiconductor region length of the first semiconductor region in the third direction, a fourth impurity concentration of the first conductivity type in the fourth semiconductor member being higher than a first impurity concentration of the first conductivity type in the first semiconductor member.

### Technical Proposal 2

The semiconductor device according to Technical proposal 1, wherein
a second semiconductor portion length of the second semiconductor portion in the third direction is longer than a first semiconductor portion length of the first semiconductor portion in the third direction.

### Technical Proposal 3

The semiconductor device according to Technical proposal 1 or 2, wherein
a third thickness of the third semiconductor portion in the first direction is smaller than a first thickness of the first semiconductor portion in the first direction, and
the third thickness is smaller than a second thickness of the second semiconductor portion in the first direction.

### Technical Proposal 4

The semiconductor device according to Technical proposal 3, wherein
the first thickness is not less than 1.3 times and not more than 2 times the third thickness.

### Technical Proposal 5

The semiconductor device according to any one of Technical proposals 1-4, wherein
at least a portion of the second semiconductor portion is provided between the third semiconductor portion and the fifth partial region in the second direction.

### Technical Proposal 6

The semiconductor device according to any one of Technical proposals 1-4, wherein
a position of the second semiconductor region in the second direction is between a position of the third semiconductor portion in the second direction and a position of the fifth partial region in the second direction.

### Technical Proposal 7

The semiconductor device according to Technical proposal 6, wherein
the fourth semiconductor member includes a high concentration region and a low concentration region,
the high concentration region is provided between the low concentration region and the second electrode,
an impurity concentration of the first conductivity type in the high concentration region is higher than an impurity concentration of the first conductivity type in the low concentration region.

### Technical Proposal 8

The semiconductor device according to any one of Technical proposals 1-4, wherein
at least a portion of the third semiconductor portion is provided between the second semiconductor portion and the fifth partial region in the second direction.

### Technical proposal 9

The semiconductor device according to any one of Technical proposals 1-4, wherein
a position of the third semiconductor portion in the second direction is between a position of the second semiconductor region in the second direction and a position of the fifth partial region in the second direction.

### Technical Proposal 10

The semiconductor device according to Technical proposal 9, wherein
the fourth semiconductor member includes a high concentration region and a low concentration region,
the high concentration region is provided between the low concentration region and the second electrode, and
an impurity concentration of the first conductivity type in the high concentration region is higher than an impurity concentration of the first conductivity type in the low concentration region.

### Technical Proposal 11

The semiconductor device according to Technical proposal 10, wherein
a position in the third direction of at least a portion of the high concentration region is between a position in the third direction of the second portion and a position in the third direction of the third semiconductor portion.

### Technical Proposal 12

The semiconductor device according to any one of Technical proposals 1-11, wherein
the second electrode includes a first electrode portion and a second electrode portion,
the first electrode portion is provided between the third semiconductor member and the second electrode portion and between the fourth semiconductor member and the second electrode portion, and
the first electrode portion includes a silicide.

### Technical Proposal 13

The semiconductor device according to any one of Technical proposals 1-12, wherein
the third semiconductor portion and the second semiconductor region are in ohmic contact with the second electrode.

### Technical Proposal 14

The semiconductor device according to any one of Technical proposals 1-13, wherein
the second semiconductor region length is 1.1 times or more the first semiconductor region length.

### Technical Proposal 15

The semiconductor device according to any one of Technical proposals 1-14, wherein
a ratio of a third width of the third semiconductor portion along the second direction to a second width of the second semiconductor region along the second direction is not less than 0.1 and not more than 10.

### Technical Proposal 16

The semiconductor device according to any one of Technical proposals 1-15, wherein
the second electrode includes a third electrode portion facing the fifth partial region, and
the third electrode portion includes at least one selected from the group consisting of Ni, Ti, V, and Mo.

### Technical Proposal 17

The semiconductor device according to any one of Technical proposals 1-16, further comprising:
a first insulating member including a first insulating region,
   at least a portion of the first insulating region being provided between the third partial region and the third electrode.

### Technical Proposal 18

The semiconductor device according to Technical proposal 17, wherein
a portion of the first insulating member is provided between the fourth semiconductor member and the third electrode.

### Technical Proposal 19

The semiconductor device according to any one of Technical proposals 1-18, further comprising:
a fifth semiconductor member of the first conductivity type,
   the fifth semiconductor member being provided between the first electrode and the first semiconductor member in the first direction, and
   a fifth impurity concentration of the first conductivity type in the fifth semiconductor member being higher than the first impurity concentration.

### Technical Proposal 20

The semiconductor device according to any one of Technical proposals 1-19, wherein
the first semiconductor member, the second semiconductor member, the third semiconductor member, and the fourth semiconductor member contain SiC.

According to the embodiments, a semiconductor device with improved characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising
a first electrode;
a second electrode;
a third electrode extending along a second direction crossing a first direction from the first electrode to the second electrode;
a first semiconductor member of a first conductivity type, the first semiconductor member including a first partial region, a second partial region, a third partial region, a fourth partial region, and a fifth partial region, the first partial region being provided between the first electrode and the third electrode in the first direction, a third direction from the first partial region to the second partial region crossing a plane including the first direction and the second direction, the third partial region being provided between the first partial region and the third electrode in the first direction, a direction from the second partial region to the fourth partial region being along the second direction, a direction from the fourth partial region to the fifth partial region being along the first direction, the fifth partial region being in Schottky contact with the second electrode;
a second semiconductor member of a second conductivity type, the second semiconductor member including a first portion and a second portion;
a third semiconductor member of the second conductivity type, the first portion being provided between the second partial region and the third semiconductor member in the first direction, a direction from at least a portion of the third semiconductor member to the fifth partial region being along the second direction, the third semiconductor member including a first semiconductor portion, a second semiconductor portion, and a third semiconductor portion, a direction from the first semiconductor portion to the third semiconductor portion being along the third direction, a direction from the third semiconductor portion to the second semiconductor portion being along the second direction, the third semiconductor portion being electrically connected to the second electrode, a third impurity concentration of the second conductivity type of the third semiconductor member being higher than a second impurity concentration of the second conductivity type of the second semiconductor member;
a fourth semiconductor member of the first conductivity type, the fourth semiconductor member including a first semiconductor region and a second semiconductor region, the first semiconductor portion being provided between the first portion and the first semiconductor region in the first direction, the second semiconductor portion being provided between the first portion and the second semiconductor region in the first direction, the second semiconductor region being electrically connected to the second electrode, the second portion being provided between the third partial region and the first semiconductor portion, between the third partial region and the first semiconductor region, between the third partial region and the second semiconductor portion, and between the third partial region and the second semiconductor region in the third direction, a second semiconductor region length of the second semiconductor region in the third direction being longer than a first semiconductor region length of the first semiconductor region in the third direction, a fourth impurity concentration of the first conductivity type in the fourth semiconductor member being higher than a first impurity concentration of the first conductivity type in the first semiconductor member.

2. The device according to claim 1, wherein
a second semiconductor portion length of the second semiconductor portion in the third direction is longer than a first semiconductor portion length of the first semiconductor portion in the third direction.

3. The device according to claim 1, wherein
a third thickness of the third semiconductor portion in the first direction is smaller than a first thickness of the first semiconductor portion in the first direction, and
the third thickness is smaller than a second thickness of the second semiconductor portion in the first direction.

4. The device according to claim 3, wherein
the first thickness is not less than 1.3 times and not more than 2 times the third thickness.

5. The device according to claim 1, wherein
at least a portion of the second semiconductor portion is provided between the third semiconductor portion and the fifth partial region in the second direction.

6. The device according to claim 1, wherein
a position of the second semiconductor region in the second direction is between a position of the third semiconductor portion in the second direction and a position of the fifth partial region in the second direction.

7. The device according to claim 6, wherein
the fourth semiconductor member includes a high concentration region and a low concentration region,
the high concentration region is provided between the low concentration region and the second electrode,
an impurity concentration of the first conductivity type in the high concentration region is higher than an impurity concentration of the first conductivity type in the low concentration region.

8. The device according to claim 1, wherein
at least a portion of the third semiconductor portion is provided between the second semiconductor portion and the fifth partial region in the second direction.

9. The device according to claim 1, wherein
a position of the third semiconductor portion in the second direction is between a position of the second semiconductor region in the second direction and a position of the fifth partial region in the second direction.

10. The device according to claim 9, wherein
the fourth semiconductor member includes a high concentration region and a low concentration region,
the high concentration region is provided between the low concentration region and the second electrode, and
an impurity concentration of the first conductivity type in the high concentration region is higher than an impurity concentration of the first conductivity type in the low concentration region.

11. The device according to claim 10, wherein
a position in the third direction of at least a portion of the high concentration region is between a position in the third direction of the second portion and a position in the third direction of the third semiconductor portion.

12. The device according to claim 1, wherein
the second electrode includes a first electrode portion and a second electrode portion,
the first electrode portion is provided between the third semiconductor member and the second electrode portion and between the fourth semiconductor member and the second electrode portion, and
the first electrode portion includes a silicide.

13. The device according to claim 1, wherein
the third semiconductor portion and the second semiconductor region are in ohmic contact with the second electrode.

14. The device according to claim 1, wherein
the second semiconductor region length is 1.1 times or more the first semiconductor region length.

15. The device according to claim 1, wherein
a ratio of a third width of the third semiconductor portion along the second direction to a second width of the second semiconductor region along the second direction is not less than 0.1 and not more than 10.

16. The device according to claim 1, wherein
the second electrode includes a third electrode portion facing the fifth partial region, and
the third electrode portion includes at least one selected from the group consisting of Ni, Ti, V, and Mo.

17. The device according to claim 1, further comprising:
a first insulating member including a first insulating region,
at least a portion of the first insulating region being provided between the third partial region and the third electrode.

18. The device according to claim 17, wherein
a portion of the first insulating member is provided between the fourth semiconductor member and the third electrode.

19. The device according to claim 1, further comprising:
a fifth semiconductor member of the first conductivity type,
the fifth semiconductor member being provided between the first electrode and the first semiconductor member in the first direction, and
a fifth impurity concentration of the first conductivity type in the fifth semiconductor member being higher than the first impurity concentration.

20. The device according to claim 1, wherein
the first semiconductor member, the second semiconductor member, the third semiconductor member, and the fourth semiconductor member contain SiC.
